(19) United States
(12) Patent Application Publication
(10) Pub. No.: US 2020/0006187 A1
(43) Pub. Date: Jan. 2, 2020

(54) Heat Dissipation Device, Semiconductor Packaging System and Method of Manufacturing Thereof

(71) Applicant: Infineon Technologies AG, Neubiberg (DE)

(72) Inventors: Ralf Otremba, Kaufbeuren (DE); Irmgard Escher-Poeppel, Duggendorf (DE); Martin Gruber, Schwandorf (DE); Michael Juerss, Regensburg (DE); Thorsten Scharf, Regensburg (DE)

(21) Appl. No.: 16/452,777

(22) Filed: Jun. 26, 2019

(30) Foreign Application Priority Data
Jun. 27, 2018 (DE) 102018115509.3

(51) Int. Cl. H01L 23/367; H01L 23/495; H01L 23/532; H01L 23/373; H01L 23/31

(52) U.S. Cl. CPC H01L 23/3675; H01L 23/49568; H01L 23/53223; H01L 23/3107; H01L 23/53266; H01L 23/3733; H01L 23/3735; H01L 23/53252

(57) ABSTRACT

A heat dissipation device includes a first part having a first material and a surface portion, and a second part on the surface portion. The second part has a second material and a porosity.

### TECHNICAL FIELD

The present invention relates to a heat dissipation device, a packaging system, and methods of manufacturing the same.

### BACKGROUND

Electronic devices often require a heat dissipation device (e.g. a heat sink) to remove thermal energy generated by the electronic devices. This is in particular true for power devices such as power packages.

A power semiconductor device usually comprises a power semiconductor die configured to conduct a load current along a load current path between two load terminals of the die. Further, the load current path may be controlled, e.g., by means of an insulated electrode, sometimes referred to as gate electrode. For example, upon receiving a corresponding control signal from, e.g., a driver, the control electrode may set the power semiconductor device in one of a conducting state and a blocking state.

After the power semiconductor die has been manufactured, it is usually installed within in a package, e.g. in a manner that allows the package with the die to be arranged within an application, e.g. in an electronic device, e.g. such that the die may be coupled to a support, e.g. a printed circuit board (PCB).

DE 10 2015 101 674 A1 discloses a package with a lead frame. The lead frame comprises a die pad to which a semiconductor chip is mounted. A main surface of the die pad remote from the semiconductor chip is at least partially exposed which allows mounting a heatsink to the package such that excess heat generated from the semiconductor chip is effectively removed. Costs for manufacturing a heat dissipation device and mounting a heat dissipation device to an electronic device is important for the industry. Related with this are performance, dimensions and reliability. The different solutions for providing an electronic device with a heat dissipation device are manifold and have to address the needs of the application.

### SUMMARY

There may be a need to manufacture a heat dissipation device and a package comprising a heat dissipation device in a simple and reliable manner.

According to a first aspect of the herein disclosed subject matter, a heat dissipation device (e.g. a heat sink) is provided. According to an exemplary embodiment, there is provided a heat dissipation device, the heat dissipation device comprising: a first part comprising a first material and having a surface portion; and a second part directly coupled to the surface portion, the second part comprising a second material; the second part having a porosity. According to a further exemplary embodiment, the heat dissipation device is manufactured according to a method according to one or more embodiments disclosed herein. According to an exemplary embodiment, there is provided a method of using a spray coating technique or a plasma spray coating technique for providing a second part of a heat dissipation device on a surface portion of a first part of the heat dissipation device, wherein the first part comprises a first material and the second part comprises a second material.

According to a second aspect of the herein disclosed subject matter a packaging system is provided. According to an exemplary embodiment, the packaging system comprises: a package comprising an electronic chip; the package having a package body encapsulating the electronic chip; the package body having an exposed heat transfer surface made of metal; and the packaging system further comprising a heat dissipation device according to the first aspect or an embodiment thereof, the heat dissipation device being thermally coupled to the heat transfer surface. According to an exemplary embodiment, a method of manufacturing a packaging system comprises: mounting to a package comprising an electronic chip a heat dissipation device according to one or more embodiments disclosed herein.

According to a third aspect of the herein disclosed subject matter, an electronic apparatus is provided. According to an exemplary embodiment, there is provided an electronic apparatus comprising a support, in particular a printed circuit board, PCB; and a packaging system according to the second aspect or an embodiment thereof, the packaging system being mounted to the support. According to a further exemplary embodiment, there is provided a method of manufacturing an electronic apparatus, the method comprising: mounting to a support a package comprising an electronic chip; thermally coupling to the package a heat dissipation device according to the first aspect or an embodiment thereof.

Those skilled in the art will recognize additional features and advantages upon reading the following detailed description, and upon viewing the accompanying drawings.

### BRIEF DESCRIPTION OF THE FIGURES

The accompanying drawings, which are included to provide a further understanding of exemplary embodiments of the herein disclosed subject matter and constitute a part of the specification, illustrate exemplary embodiments of the invention. The illustration in the drawings is schematic and not to scale.

In the drawings:

FIG. 1 illustrates a cross-sectional view of a heat dissipation device according to embodiments of the herein disclosed subject matter.

FIG. 2 illustrates a cross-sectional view of a further heat dissipation device according to embodiments of the herein disclosed subject matter.

FIG. 3 illustrates a cross-sectional view of a further heat dissipation device according to embodiments of the herein disclosed subject matter.

FIG. 4 illustrates a cross-sectional view of a part of the heat dissipation device of FIG. 1.

FIG. 5 illustrates a perspective view of an electronic apparatus according to embodiments of the herein disclosed subject matter.

FIG. 6 illustrates a perspective view of a further electronic apparatus according to embodiments of the herein disclosed subject matter.

FIG. 7 illustrates a cross-sectional view of a packaging system according to embodiments of the herein disclosed subject matter.

FIG. 8 illustrates a cross-sectional view of a further packaging system according to embodiments of the herein disclosed subject matter.

FIG. 9 illustrates a cross-sectional view of a further electronic apparatus according to embodiments of the herein disclosed subject matter.

FIG. 10 illustrates a cross-sectional view of a further electronic apparatus according to embodiments of the herein disclosed subject matter.

### DETAILED DESCRIPTION

In the following, further exemplary embodiments of the heat dissipation device, the packaging system, the electronic apparatus, and the methods are described, any number and any combination of which may be realized in an implementation of aspects of the herein disclosed subject matter.

In the context of the present application, the term “package” may particularly denote at least one at least partially encapsulated electronic chip with at least one external electric contact, also referred to as outlead terminal.

The term “electronic chip” may particularly denote a semiconductor chip having at least one integrated circuit element (such as a diode or a transistor), e.g. in a surface portion thereof. The electronic chip may be a naked die or may be already packaged or encapsulated by an encapsulant.

In the context of the present application, the term “encapsulant” may particularly denote a substantially electrically insulating and preferably thermally conductive material surrounding (for example hermetically surrounding) an electronic chip and part of a carrier to provide mechanical protection, electrical insulation, and optionally a contribution to heat removal during operation. Such an encapsulant can be, for example, a mold compound.

In the context of the present application, the term “carrier” may particularly denote an electrically conductive structure, such as a leadframe, which serves as a support for one or more of the electronic chips, and which may also contribute to the electric interconnection between the chip(s) and one or more further components (e.g. outlead terminals). In other words, the carrier may fulfil a mechanical support function and an electric connection function. Further, the carrier may comprise several parts which are electrically separated, at least in the final product (after packaging). Accordingly, the carrier may also be referred to as a carrier structure (or, in case of a leadframe, as a leadframe structure).

In the context of the present application, the term “component” may particularly denote a carrier or any electronic member which can be connected to the carrier to provide its electronic function to the package. In particular, the component may be a passive component such as an inductor (in particular a coil), a capacitor (such as a ceramic capacitor), an ohmic resistance, an inductance, a diode, a transformer, etc. In particular components being not capable of controlling current by another electrical signal may be denoted as passive components. However, the component may also be an active component, in particular may be a component being capable of controlling current by another electrical signal. Active components may be an analog electronic filter with the ability to amplify a signal or produce a power gain, an oscillator, a transistor or another integrated circuit element. In particular, the component may be any Surface Mounted Device (SMD), may be any through-hole device (THD), may be a sensor, a light-emitting diode or a laser diode. In another embodiment, the component is a package as well, in particular an encapsulated further electronic chip.

In accordance with an embodiment, the second part has a porosity (i.e. a volume fraction of the second part consists of pores). In other words, according to an embodiment, the second part is porous/is made from a porous material. According to an embodiment, the heat dissipation device comprises a first part and a second part. According to an embodiment, the porosity of the second part is larger than 0.1% (in other words, the volume fraction of the pores of the second part is larger than 0.1% of the total volume of the second part). According to an embodiment, the porosity of the second part is in a range between 0.1% and 30%, in particular between 1% and 20%, further in particular between 3% and 15%. A porosity of this type may be achieved by a method of manufacturing a heat dissipation device according to embodiments of the herein disclosed subject matter. In particular, porosity of this type may be achieved by depositing particles of the second material on the surface portion of the first part. According to an embodiment, the thus deposited particles of the second material form the second part.

According to an embodiment, the first material of the first part is a metal. For example, according to an embodiment, the first material is a metal that forms a natural oxide layer on its surface. According to an embodiment the first material comprises at least one of aluminum and magnesium. Aluminum has a comparatively low density and hence allows to manufacture a lightweight heat dissipation device at reasonable costs. However, often the natural oxide layer formed on the surface of aluminum may adversely affect the attachment of the heat dissipation device to a heat transfer surface. By providing the first part of the heat dissipation device with the second part, comprising a second material, the second material may be selected so as to allow usage of the desired attachment material. The porosity of the second part may further improve the reliability of the attachment of the heat dissipation device to the heat transfer surface.

According to an embodiment, the first material is different from the second material. According to a further embodiment, the second material is a metal. For example, according to an embodiment the second material comprises at least one of copper (Cu), a copper alloy, a copper-zinc alloy (Cu—Zn alloy), a copper-tin alloy (Cu—Sn), silver (Ag), a silver alloy, bronze, and brass.

According to an embodiment, the second part of the heat dissipation device comprises a solderable surface. According to a further embodiment, the second material comprises a solderable material, for example copper.

According to a further embodiment, the second part has an average thickness larger than 30 μm (micrometer), in particular larger than 50 μm and further in particular larger than 100 μm. For example, according to an embodiment the average thickness of the second part may be in a range between 30 μm and 1 mm (millimeter), for example between 30 μm and 500 μm, in particular in a range between 50 μm and 200 μm. By providing the second part with such a substantial average thickness, the second part acts as an intermediate heat spreader between the heat transfer surface and the first part of the heat dissipation device.

According to an embodiment, the thermal conductivity of the second material is higher than a thermal conductivity of the first material. According to an embodiment the first material may be Al or an Al alloy with a thermal conductivity in range of 80 W/mK-230 W/mK and the second material could be Cu or a Cu alloy with a thermal conductivity in range of 100 W/mK-400 W/mK).

This may allow to reduce at least one dimension of the first part, thus allowing to make the entire heat dissipation device more compact.

According to an embodiment, the second part comprises a plurality of pores at least part of which is filled with a third material. For example, according to an embodiment the third material may have a higher corrosion resistance than the second material. In this way, the corrosion resistance of the second part may be improved.

According to an embodiment, an interface between the first part and the second part comprises a certain surface roughness. Unless explicitly noted otherwise, herein the term “roughness” refers to the root mean square roughness (rms roughness) as defined in a common normatives. According to an embodiment, a root mean square roughness of the interface between the first part and the second part is in a range between 1 μm and 100 μm, in particular between 5 μm and 40 μm, further in particular between 10 μm and 40 μm. The roughness of the interface may improve the adhesion between the first part and second part. According to an embodiment, the RMS roughness is measured over a length of 1 mm.

According to a further embodiment, the second part has thermal properties different from thermal properties of the first part, e.g. different from thermal properties of the first material. According to an embodiment, the second part is a material layer, i.e. a material layer comprising the second material. According to a further embodiment, the material layer has thermal properties different from thermal properties of the first part.

According to an embodiment, at least one of the heat transfer surface and the second part comprises two or more individual portions. In other words, according to an embodiment the two or more individual portions are (laterally) spaced from each other. According to an embodiment, the material layer is patterned, i.e. the second part is a patterned material layer. For example, according to an embodiment the pattern (i.e. the geometrical shape) of the second part may be adapted to the heat transfer surface, in particular wherein the heat transfer surface comprises two or more individual surface portions (e.g. if the heat transfer surface is formed from two or more individual components) which share the same (i.e. a single) heat dissipation device. For example according to an embodiment the pattern of the second part may provide an individual thermal contact portion for each individual surface portion of the heat transfer surface.

According to an embodiment, the surface portion of the heat dissipation device comprises the first material. For example, according to an embodiment the first part consists of a body comprising the first material. According to a further embodiment, the surface portion is formed by the first material. For example, according to an embodiment the body is made from the first material. For example, according to an embodiment the first part is formed from aluminum, for example a single piece of aluminum, which comprises the surface portion. Aluminum has the advantage of being lightweight and inexpensive. Further, aluminum has a good thermal conductivity.

According to an embodiment, the first part comprises a further layer, e.g. barrier layer and/or an adhesion layer and/or an adhesion promotion layer. According to a further embodiment, the adhesion promotion layer comprises one or more of aluminum (Al), titanium (Ti), nickel (Ni), gold (Au) and/or an alloy of one or more of aluminum (Al), titanium (Ti), nickel (Ni), gold (Au). For example, according to an embodiment the first part comprises a body (e.g. the above-described body) and a further layer, the further layer being located between the body and the second part, the further layer exhibiting the surface portion. According to an embodiment, the barrier layer (in particular the material from which the barrier layer is formed) is configured for preventing a chemical reaction and/or an interdiffusion of the first material and the second material. For example, according to an embodiment the barrier layer prevents formation of (undesired) intermetallic phases from the first material and the second material. For example, according to an embodiment the barrier layer comprises one or more of nickel (Ni), titanium (Ti), titanium nitride (TiN) and chromium (Cr).

According to a further embodiment, the heat dissipation device further comprises an attachment material on the second part. According to an embodiment, the attachment material is configured for attachment of the heat dissipation device to the heat transfer surface. According to an embodiment, the attachment material comprises at least one of (i) a solder, in particular a soft solder, a solder paste, or a diffusion solder; (ii) a thermal interface material; (iii) a sinterable material. According to an embodiment, the attachment material is applied by depositing particles of the attachment material on to the second part. For example, according to an embodiment the attachment material is applied to the second part by spray coating or plasma spray coating.

According to an embodiment, the attachment material is configured (e.g. the amount of attachment material is sufficient) so as to provide a form-fit connection to the heat transfer surface. In other words, according to an embodiment the attachment material is configured so as to level out a surface roughness (or surface structure) of the second part and/or the heat transfer surface.

According to an embodiment, a packaging system comprises a package comprising an electronic chip and a heat dissipation device (according to one or more embodiments of the herein disclosed subject matter) attached to the package, in particular by an attachment material disclosed herein. For example, according to an embodiment the package comprises a heat transfer surface (e.g. a surface from which heat is to be removed) and the heat dissipation device is attached to the heat transfer surface.

According to a further embodiment, the package (e.g. the packaging system) is mounted on a first main surface of a support, in particular a printed circuit board, and the heat transfer surface (or e.g. a second heat transfer surface) is provided on a second main surface of the support which is opposite (i.e. faces away from) the first main surface. A thermal connection between them first main surface and the second main surface may be achieved by a plurality of vias extending between the first main surface and the second main surface. According to a further embodiment, the package may comprise a further heat transfer surface which is opposite the support, wherein a further heat dissipation device is attached to the further heat transfer surface. In this way, cooling of the electronic apparatus (comprising the package and the printed circuit board) is possible from two sides of the electronic apparatus.

According to an embodiment, the electronic chip comprises (e.g. is) a semiconductor chip, in particular a power semiconductor chip, e.g. a vertical current device, in particular an insulated gate bipolar transistor (IGBT), a metal oxide field effect transistor (MOSFET), a silicon carbide (SiC) device or a gallium nitride (GaN) device. For example a power semiconductor chip may be configured for a rated power of about 100 watt, resulting in 5 watt heat generation for an assumed efficiency of about 95%. In particular for power semiconductor chips, electric reliability and mechanical integrity are important issues which can be met with a heat dissipation device as described herein. According to an embodiment, a power semiconductor chip is a chip with vertical power flow (i.e. a vertical current device, in particular a chip with a load electrode (e.g. a single load electrode) on each of opposing sides of the chip. According to an embodiment, a power semiconductor chip comprises at least one of an insulated gate bipolar transistor, a field effect transistor, (such as a metal oxide semiconductor field effect transistor), a diode, etc. With such constituents, it is possible to provide packages for automotive applications, high-frequency applications, etc. Examples for electric circuits which can be constituted by such and other power semiconductor circuits and packages are half-bridges, full bridges, etc. However, the heat dissipation device disclosed herein may be advantageous for any device that requires heat to be dissipated. In particular, the heat dissipation device according to embodiments of the herein disclosed subject matter may be reliably mechanically attached and thermally coupled to a heat transfer surface by soldering the second part to the heat transfer surface.

According to an embodiment, the first part comprises a further surface portion (which may be referred to as second surface portion) opposite the surface portion (which may be referred to as first surface portion), wherein the further surface portion is configured for receiving a further heat dissipation device. According to a further embodiment, the further surface portion is provided by an iso interface, e.g. an interface with a thickness of 152 μm and a thermal conductivity of 2.3 watt per meter and kelvin (W/mK) (also referred to as K10 interface).

According to an embodiment, an interface (e.g. an iso interface) is provided between two or more packages and the heat dissipation device. According to a further embodiment, the interface may be configured to contact the two or more packages electrically isolated (or, in another embodiment electrically connected) and thermally coupled to a common heat dissipation device according to embodiments of the herein disclosed subject matter.

In accordance with the method of manufacturing a heat dissipation device according to embodiments of the herein disclosed subject matter, the method comprises providing a first part comprising a first material and having a surface portion, and depositing particles of the second material on the surface portion to thereby form the second part.

According to a further embodiment, the depositing of the particles of the second material comprises transporting the particles in a fluid stream (e.g. in a gas stream, i.e. according to an embodiment the fluid is a gas, e.g. air or nitrogen) onto the surface portion. For example, according to an embodiment the depositing of the particles of the second material is performed by a spray coating (or plasma spray coating) the particles of the second material onto the surface portion. To this end, any suitable spray coating technique known in the art may be used. Surprisingly, the inventors found that spray coating (e.g. plasma spray coating) is a suitable deposition technique to achieve desirable properties of the second part as described herein.

According to a further embodiment, the kinetic energy of the particles of the second material is sufficient so as to deform the surface portion upon impingement of the particles on the surface portion. For example according to an embodiment, the fluid stream has a velocity of at least 20%-120% of the velocity of sound in the fluid.

The formation of the surface portion by the impinging particles of the second material results in a good adhesion of the particles on the surface portion.

According to an embodiment, the method further comprises providing a plasma, in particular wherein the fluid stream comprises the plasma (e.g. the fluid stream may comprise ions and/or the particles are charged particles). According to a further embodiment, the depositing of the particles is a plasma assisted depositing of the particles. According to a further embodiment the plasma is configured so as to provide the particles as reactive particles.

Depending on the embodiment(s) implemented in the actual method of manufacturing a heat dissipation device, the resulting heat dissipation device may exhibit one or more properties described herein with reference to respective embodiments of the heat dissipation device.

Depositing of particles of the second material on the surface portion has the advantage that a relatively large amount of second material can be deposited on the surface portion in a comparatively small amount of time (e.g. compared to electroplating).

In an embodiment, the electronic chip comprises at least one of the group consisting of a controller circuit, a driver circuit, and a power semiconductor circuit. All these circuits may be integrated into one semiconductor chip, or separately in different chips. For instance, a corresponding power semiconductor application may be realized by the chip, wherein integrated circuit elements of such a power semiconductor chip may comprise at least one transistor such as at least one insulated gate bipolar transistor (IGBT) and/or at least one field effect transistor and/or at least one silicon carbide (SiC) device and/or at least one gallium nitride (GaN) device, (in particular a MOSFET, metal oxide semiconductor field effect transistor), at least one diode, etc. In particular, circuits fulfilling a half-bridge function, a full-bridge function, etc., may be manufactured.

In an embodiment, the electronic chip is directly mounted (in particular are directly soldered, sintered or glued) on a main surface of an electrically conductive carrier, e.g. a leadframe. According to an embodiment the carrier comprises a metal, e.g. copper. According to a further embodiment, the carrier (e.g. a copper leadframe) is coated with a coating material, e.g. a metal, such as nickel. According to a further embodiment, the lead frame comprises a die pad to which the electronic chip is mounted. According to a further embodiment, the package body encapsulates the carrier at least partially. According to an embodiment, an outlead of the package is exposed. Further, according to an embodiment one side of the die pad and/or a contact clip is at least partially uncovered from the encapsulant (i.e. one side of the die pad and/or a contact clip is at least partially exposed with regard to the encapsulant). For instance, according to an embodiment, one side of the die pad and/or one side of the contact clip is exposed with regard to the encapsulant (double side cooling package).

In an embodiment, the (at least one) electronic chip, is encapsulated by an encapsulant which may comprise a mold material. For instance, a correspondingly encapsulated part (in particular chip with carrier, component) may be provided by placing the part or parts between an upper mold tool and a lower mold tool and to inject liquid mold material therein. After solidification of the mold material, formation of the encapsulant is completed. If desired, the mold material may be filled with particles improving its properties, for instance its heat removal properties.

In an embodiment, a contact clip which is thermally and electrically coupled to the electronic chip is partially exposed with regard to the encapsulant. In other words, the contact clip may be only partially covered with the encapsulant so that at least a heat transfer surface remains uncovered from the encapsulant. Allowing the transfer surface to extend out of the encapsulant promotes and simplifies heat removal, which is of utmost importance for power semiconductor applications. According to an embodiment, the electronic chip comprises a first surface and an opposing second surface. According to a further embodiment, the first surface of the electronic chip is electrically coupled to (e.g. a soldered, sintered or glued to) an electrically conductive carrier e.g. a lead frame. According to a further embodiment, an electrically conductive clip electrically connects the electrically conductive carrier and the second surface of the electronic chip. For example, according to an embodiment, the first surface of the electronic chip comprises a first load electrode (e.g. a drain electrode) and the second surface of the electronic chip comprises a second load electrode (e.g. a source electrode) wherein the electrical connection to the first and second surface is an electrical connection to the respective load electrode. If the electronic chip comprises a gate electrode, in accordance with an embodiment second surface comprises the gate electrode which is electrically coupled to the electrically conductive carrier by a further electrically conductive clip. According to an embodiment, the electrically conductive clip is exposed with regard to the encapsulant and forms the heat transfer surface.

According to an embodiment, the heat dissipation device is attached to a main surface of the electrically conductive clip being uncovered by encapsulant material and being exposed to an environment of the package, so that heat generated by the at least one electronic chip during operation of the package can be removed or dissipated from the package by the heat dissipation device. The exposed main surface of the electrically conductive clip then acts as a heat transfer surface in the sense of embodiments of the herein discloses subject matter. According to another embodiment, the package comprises a heat transfer surface which is spaced from but thermally coupled to the (at least one) electronic chip of the package.

In an embodiment, a method comprises electrically connecting the package, and a support, e.g. by soldering. As mentioned above, sintering and gluing are alternatives to soldering.

According to an embodiment, the heat dissipation device is attached to heat transfer surface by an attachment material. For example, according to an embodiment, the attachment material comprises at least one of (i) a solder, in particular a soft solder, a solder paste, or a diffusion solder; (ii) a thermal interface material; (iii) a sinterable material. In particular soldering provides a good and reliable mechanical and thermal connection.

According to a further embodiment the second part of the heat dissipation device is a heat spreader, distributing the heat from the heat transfer surface to the surface portion. For example, in particular if the second material is a material of high thermal conductivity (e.g. if a thermal conductivity of the second material is higher than a thermal conductivity of the first material), the second part made of this second material may act as a heat spreader (e.g. depending on the geometry of the second part). For example, according to an embodiment, an area of the surface portion is larger than an area of the heat transfer surface. According to an embodiment, an area of the surface portion amounts to at least 120% of the area of the heat transfer surface. Due to the larger area, the heat provided at the heat transfer surface is spread to the larger area of the surface portion.

According to an embodiment, the package further comprises a leadframe with an exposed portion configured to electrically and/or mechanically couple the package to a support. According to a further embodiment, the leadframe comprises a die pad to which the electronic chip is attached. According to a further embodiment, the exposed portion is an exposed portion of the die pad (e.g. a rear surface of the die pad which is opposite a front surface of the die pad to which the electronic chip is attached).

According to a further embodiment, the package body has a first side (e.g. a top side), a second side (e.g. a bottom side) and sidewalls extending between the second side and the first side, the second side facing the support; the leadframe comprises at least one outlead terminal being exposed at or extending out of the second side or at least one of the sidewalls, the at least one outlead terminal being electrically connected to the electronic chip.

According to an embodiment, the package further comprises an exposed outlead terminal at the first side. According to an embodiment the outlead terminal forms at least part of the heat transfer surface. For example, the heat transfer surface of the package (to which the heat dissipation device is attached) may be located on the first side of the package body.

According to a further embodiment, the heat transfer surface has an area amounting to at least 50% and to less than 100% of the total area of the first side. In other words, according to an embodiment the heat transfer surface does not completely cover the first side of the package but only covers a portion of at least 50% of the first side of the package.

According to an embodiment, the electronic chip is a semiconductor chip, in particular a power semiconductor chip having a first load terminal (one of a source/drain electrode) and a second load terminal (e.g. the other of the source/drain electrode). For example, the power semiconductor chip may be diode, in particular a diode having only two terminals, the first load terminal and the second load terminal. If, in another example, the power semiconductor chip is a transistor, the power semiconductor chip may comprise at least one control electrode (e.g. a gate electrode) for controlling the conductivity of the path between the first load terminal and the second load terminal.

In the above there have been described and in the following there will be described exemplary embodiments of the subject matter disclosed herein with reference to a heat dissipation device, a package, an electronic apparatus, and various methods. It has to be pointed out that of course any combination of features relating to different aspects of the herein disclosed subject matter is also possible. In particular, some features have been or will be described with reference to device type embodiments whereas other features have been or will be described with reference to method type embodiments. However, it should be understood from the above and the following description that, unless otherwise notified, in addition to any combination of features belonging to one aspect also any combination of features relating to different aspects or embodiments, for example even combinations of features of device type embodiments and features of the method type embodiments are considered to be disclosed with this application. In this regard, it should be understood that any method feature derivable from a corresponding explicitly disclosed device feature should be based on the respective function of the device feature and should not be considered as being limited to device specific elements disclosed in conjunction with the device feature. Further, it should be understood that any device feature derivable from a corresponding explicitly disclosed method feature can be realized based on the respective function described in the method with any suitable device feature disclosed herein or known in the art.

The above and other objects, features and advantages of the herein disclosed subject matter will become apparent from the following description and the appended claims (to which the invention is not limited), taken in conjunction with the accompanying drawings, in which like parts or elements are denoted by like reference numbers. The aforementioned definitions and comments are in particular also valid for the following description and vice versa.

Before exemplary embodiments will be described in more detail referring to the Figures, some general considerations will be summarized based on which exemplary embodiments have been developed.

Solder as used in some embodiments of the herein disclosed subject matter is a metal or metal alloy that is fusible in an suitable temperature range which does not damage the electronic chip or other components of the package or the support. Soft solders typically have a melting point in a range from 100° C. to 450° C. According to an embodiment, the solder comprises at least one of a lead-tin solder (Pb—Sn), nickel-gold solder (Ni—Au), palladium-gold solder (Pd—Au), nickel-palladium-gold-silver solder (Ni—Pd—Au—Ag).

Diffusion solders typically have a first melting temperature when applied. After application and typically under a certain pressure the diffusion solder forms intermetallic phases with the participating metals to be connected, wherein the intermetallic phases typically have a higher melting point than the initial diffusion solder.

Solders can be applied as a pad, as a paste or can be spray coated, just to name some examples. Besides the solders explicitly mentioned herein, any other suitable solder may be used in other embodiments.

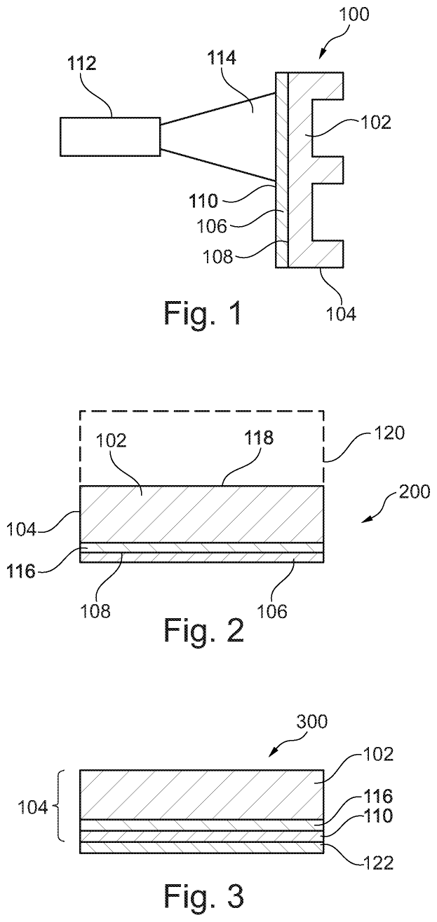

FIG. 1 illustrates a cross-sectional view of a heat dissipation device 100 according to embodiments of the herein disclosed subject matter.

In accordance with an embodiment, the heat dissipation device 100 (e.g. a heat sink as shown in FIG. 1) comprises a body 102 which comprises a first material, e.g. aluminum. According to an embodiment, the body 102 is made from aluminum. The body may have a complex three dimensional shape, e.g. as shown in FIG. 1, so as to provide a large surface area. In accordance with an embodiment, the body 102 forms a first part 104 of the heat dissipation device 100.

According to a further embodiment, the heat dissipation device 100 comprises a material layer 106 comprising a second material, e.g. copper, on a surface portion 108 of the first part 104. In accordance with a further embodiment, the material layer 106 forms of a second part 110 of the heat dissipation device 100.

In accordance with an embodiment, the material layer 106 is solderable, thus allowing the heat dissipation device 100 to be soldered to a heat transfer surface (not shown in FIG. 1).

In accordance with an embodiment, a spray coating device 112 is provided for transporting particles of the second material in a fluid stream 114 (e.g. a gas stream) to the surface portion 108 and deposit the particles on the surface portion 108.

FIG. 2 illustrates a cross-sectional view of a further heat dissipation device 200 according to embodiments of the herein disclosed subject matter.

According to an embodiment, the first part 104 comprises the body 102 and a barrier layer 116, e.g. a nickel layer. According to an embodiment, the surface portion 108 is formed by the barrier layer 116. According to a further embodiment, the second part is located on the surface portion 108.

According to a further embodiment, the first part 104 comprises a further surface portion 118 opposite the surface portion 108. According to an embodiment, the further surface portion is provided for (e.g. configured to) receiving a further heat dissipation device 120. For example, in an embodiment the further surface portion 118 may be a surface portion with defined properties such as surface area, surface roughness, thermal conductivity, material, etc. For example, the first part may be provided at a premises of a manufacturer of the heat dissipation device or a manufacturer of an package, to which the heat dissipation device is mounted in an embodiment, while the further heat dissipation device 120 may be mounted to the heat dissipation device 200 at a premises of a customer.

FIG. 3 illustrates a cross-sectional view of a further heat dissipation device 300 according to embodiments of the herein disclosed subject matter.

The heat dissipation device 300 is similar to the heat dissipation device 200 illustrated in FIG. 2 and further comprises an attachment material 122, e.g. a solder, on the second part 110. According to another embodiment, the attachment material is provided on the heat transfer surface (not shown in FIG. 3). According to an embodiment, the attachment material 122 is provided as a continuous layer, as shown in FIG. 3. According to an embodiment, the attachment material may be provided in another shape, e.g. as a structured layer, or as a bump.

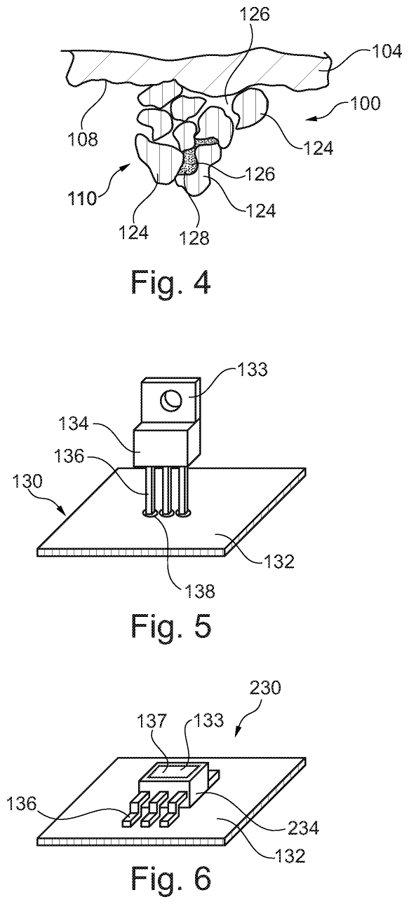

FIG. 4 illustrates a cross-sectional view of a part of the heat dissipation device 100 of FIG. 1.

According to an embodiment, the heat dissipation device 100 comprises on its surface portion 108 a plurality of particles 124 which together form the second part 110. In accordance with an embodiment, the second part has a porosity larger than 0.1% and includes a plurality of pores 126. In accordance with an embodiment, at least part of the pores is filled with a third material 128. The third material may improve the corrosion resistance of the second part 110. According to an embodiment, the third material is provided in the pores by in situ spray coating or plasma spray coating of the third material. In other words, according to an embodiment the third material may be deposited in the pores by spray coating or plasma spray coating (i) after depositing the particles of the second material without removing the heat dissipation device from the deposition atmosphere (which may be vacuum), and/or (ii) concurrently with the depositing of the particles of the second material.

As schematically shown in FIG. 4, the interface between the first part 104 and the second part 110 may have a certain surface roughness which may arise from the impinging particles 124 on the surface portion 108.

FIG. 5 illustrates a perspective view of an electronic apparatus 130 according to embodiments of the herein disclosed subject matter.

In accordance with an embodiment, the electronic apparatus 130 comprises a support 132 and a package 134 mounted to the support 132. A part of a lead frame 133 is exposed with regard to the encapsulant of the package 134. According to an embodiment, a heat dissipation device (not shown) may be attached to a rear side (i.e. a side facing away from the electronic chip, not shown in FIG. 5) of the lead frame 133. In accordance with an embodiment, the package 134 is a through hole device, e.g. a transistor outlet device (TO device), as shown in FIG. 5, with leads 136 of the package 134 extending through holes 138 of the support 132.

FIG. 6 illustrates a perspective view of a further electronic apparatus 230 according to embodiments of the herein disclosed subject matter.

In accordance with an embodiment, an package 234 is mounted to the support 132 as a surface mount device (SMD) of which leads 136 are attached (e.g. soldered) to conductive pads (not shown in FIG. 6) on the support 132. According to an embodiment, a lead frame 133 comprises a die pad 137 having a main surface which is at least partially exposed with regard to the encapsulant (i.e. which is not covered by the encapsulant). A semiconductor chip (e.g. a die, not shown in FIG. 6) is mounted on a main surface of the die pad 137 opposite the at least partially exposed main surface.

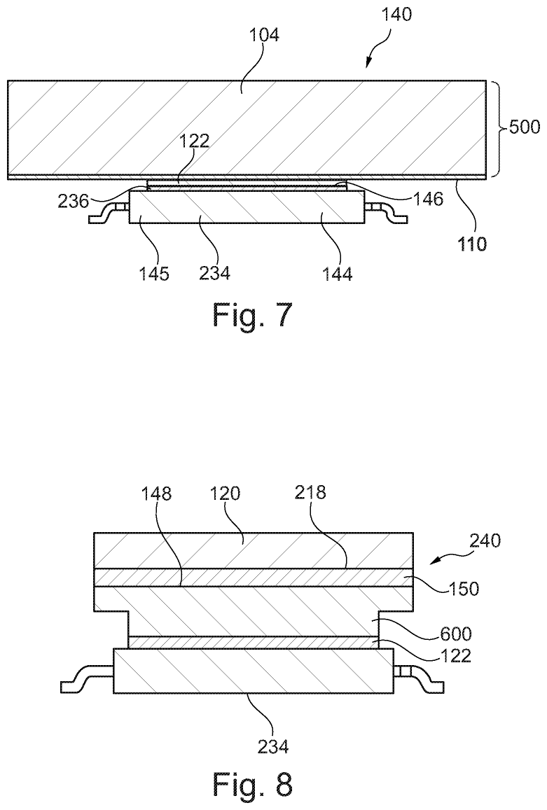

FIG. 7 illustrates a cross-sectional view of a packaging system 140 according to embodiments of the herein disclosed subject matter.

The packaging system 140 includes, in accordance with an embodiment, a package 234 illustrated as a surface mount device. In accordance with an embodiment, the package 234 includes a semiconductor chip (not shown in FIG. 7) encapsulated by an encapsulant 144. In accordance with an embodiment, the encapsulant 144 forms (constitutes) a package body 145 or at least part of a package body). According to an embodiment, the package 234 comprises a heat transfer surface 146 which may be formed for example by a metal layer 236, e.g. a copper layer. According to an embodiment, the metal layer 234 is an exposed portion of a lead frame to which the semiconductor chip is mounted.

According to an embodiment, the packaging system further comprises a heat dissipation device 500 comprising a first part 104 and a second part 110. Between the second part 110 of the heat dissipation device 500 and the heat transfer surface 146 of the package 234 a solder paste is provided as attachment material 122. Other attachment materials may of course be used in other embodiments.

FIG. 8 illustrates a cross-sectional view of a further packaging system 240 according to embodiments of the herein disclosed subject matter.

In accordance with an embodiment, the packaging system 240 comprises an package 234. Further, the packaging system 240 comprises a heat dissipation device 600, acting as an intermediate heat spreader. The heat dissipation device is 600 is attached to the package 234 by an attachment material 122, e.g. a solder, which may also be referred as a “chip-heatspreader-interconnect”.

According to an embodiment, the heat dissipation device 600 comprises an interface layer 150 on a surface 148 which is located opposite the attachment material 122, e.g. as shown in FIG. 8. According to an embodiment, the interface layer 150 provides a further surface portion 218 to which a further heat dissipation device 120, e.g. a customer heat dissipation device is attached (or is attachable). According to an embodiment, the interface layer 150 is an interface layer with defined characteristics, e.g. an ISO interface.

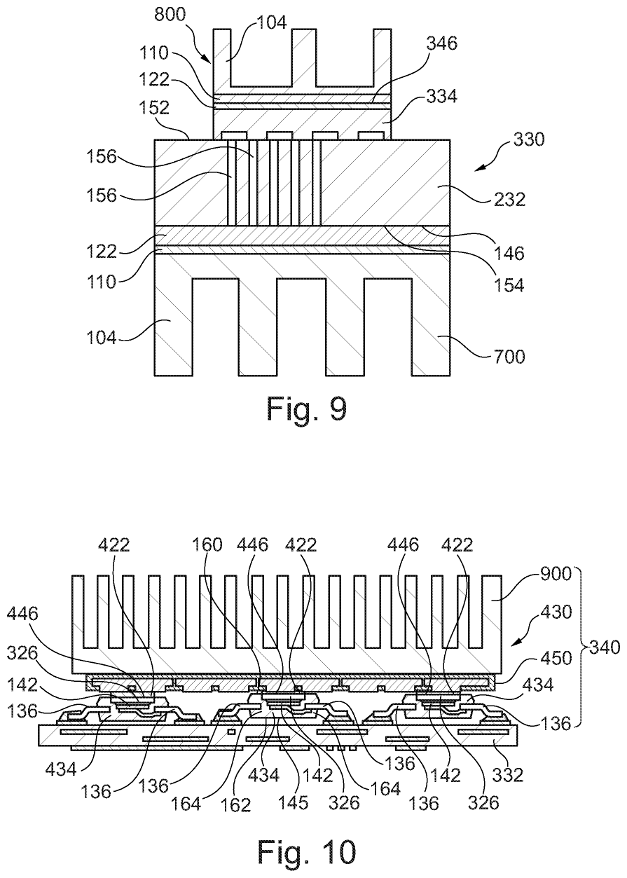

FIG. 9 illustrates a cross-sectional view of a further electronic apparatus 330 according to embodiments of the herein disclosed subject matter.

According to an embodiment, the electronic apparatus 330 comprises a support 232 and an package 334 mounted to the support 232 on a first main surface 152. The support 232 comprises a second main surface 154. According to a further embodiment, the electronic apparatus 330 comprises a heat dissipation device 700 according to embodiments of the herein disclosed subject matter. According to a further embodiment, a heat transfer surface 246 to which a heat dissipation device 700 is attached by an attachment material 122, is the second main surface 154 of the support 232. In order to thermally couple the package 334 to the heat dissipation device 700, a plurality of vias 156 is provided in the support 232. The vias 156 may be formed of the same material from which connecting vias, which electrically connect different metallization layers of the support (not shown in FIG. 9), are formed.

According to a further embodiment, the package also provides a further heat transfer surface 346 which is opposite (i.e. remote from) the support 232. In accordance with an embodiment, a further heat dissipation device 800 is attached to the further heat transfer surface 346 by an suitable attachment material 122. According to an embodiment, both the heat dissipation device 700 and the further heat dissipation device 800 comprises a first part and a second part according to embodiments of the herein disclosed subject matter.

FIG. 10 illustrates a cross-sectional view of a further electronic apparatus 430 according to embodiments of the herein disclosed subject matter.

In accordance with an embodiment, at least two packages 434 (e.g. three packages, as shown in FIG. 10) each of which comprises a semiconductor chip 142 which is electrically connected by leads 136 (e.g. outlead terminals as shown in FIG. 10) to a support 332, e.g. a printed circuit board as shown in FIG. 10. Thermally coupled to the semiconductor chip 142 is a metal element, e.g. a metal layer 326, which forms a heat transfer surface 446 to which an interface 450 is attached e.g. by an attachment material 422, e.g. a solder. According to an embodiment, the metal layer 326 is a die pad of a lead frame on which the semiconductor chip 142 is mounted or, in another embodiment, a contact clip. In accordance with an embodiment, the interface 450 thermally couples the at least two packages 434. In accordance with a further embodiment, the interface 450 does not electrically connect the at least two packages 434. In other words, the interface 450 electrically isolates the at least two packages 434. It should be noted that of course the at least two packages 434 may be (nonetheless) electrically coupled by the support 332.

According to an embodiment, the package body 145 of each package 434 has a first side 160, a second side 162 and sidewalls 164 from which the leads 136 extend out of the package body 145. In accordance with an embodiment, at least some of the leads 136 are portions of a leadframe to which the electronic chip 142 is mounted.

According to an embodiment, the electronic chip 142 is a vertical current device wherein the die pad (metal layer 326) is electrically connected to a load electrode of the electronic chip 142.

In accordance with a further embodiment, a heat dissipation device 900 (e.g. a heatsink as shown in FIG. 10) is attached to the interface 450, e.g. by an attachment material (not shown in FIG. 10). Accordingly, the assembly of the at least two packages 434, the interface 450 and the heat dissipation device 900 may be considered a packaging system in the sense of the herein disclosed subject matter. The heat dissipation device 900 may be configured according to one or more embodiments of the herein disclosed subject matter.

According to an embodiment the term “adapted to” includes inter alia the meaning “configured to”.

It should be noted that the term “comprising” does not exclude other elements or features and the “a” or “an” does not exclude a plurality. Further, the term “comprising” includes the meaning “inter alia comprising” as well as the meaning “consisting of”. In other, words, the term “comprising copper” includes “comprising inter alia copper” and “consisting of copper”. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A heat dissipation device, comprising:
a first part comprising a first material and having a surface portion; and
a second part directly coupled to the surface portion and comprising a second material,
wherein the second part has a porosity,
wherein the first part further comprises a barrier layer and/or an adhesion layer and/or an adhesion promotion layer.

2. The heat dissipation device of claim 1, wherein the porosity of the second part is in a range between 0.1% and 30%.

3. The heat dissipation device of claim 1, wherein the first material comprises aluminum, aluminium alloy, magnesium, and/or magnesium alloy.

4. The heat dissipation device of claim 1, wherein the second material is different from the first material.

5. The heat dissipation device of claim 1, wherein a thermal conductivity of the second material is higher than a thermal conductivity of the first material.

6. The heat dissipation device of claim 1, wherein the second material comprises copper, copper alloy, silver, silver alloy, bronze and/or brass.

7. The heat dissipation device of claim 1, wherein the second part is a material layer having thermal properties different from thermal properties of the first part.

8. The heat dissipation device of claim 7, wherein the material layer is a patterned material layer.

9. The heat dissipation device of claim 1, wherein the barrier layer comprises nickel, titanium, titanium nitride, and/or chromium.

10. The heat dissipation device of claim 1, wherein the adhesion promotion layer comprises aluminum, titanium, nickel, gold and/or an alloy of aluminum, titanium, nickel and/or gold.

11. A packaging system, comprising:
a package comprising an electronic chip, the package having a package body encapsulating the electronic chip, the package body having an exposed heat transfer surface made of metal; and
a heat dissipation device thermally coupled to the heat transfer surface, the heat dissipation device comprising a first part comprising a first material and having a surface portion, and a second part directly coupled to the surface portion and comprising a second material, the second part having a porosity, the first part further comprising a barrier layer and/or an adhesion layer and/or an adhesion promotion layer.

12. The packaging system of claim 11, wherein the heat dissipation device is attached to the heat transfer surface by an attachment material.

13. The packaging system of claim 12, wherein the attachment material comprises:
a soft solder, a solder paste, or a diffusion solder;
and/or a thermal interface material; and/or
a sinterable material.

14. The packaging system of claim 11, wherein an area of the surface portion is larger than an area of the heat transfer surface.

15. The packaging system of claim 11, wherein an area of the surface portion amounts to at least 120% of an area of the heat transfer surface.

16. The packaging system of claim 11, further comprising:
a leadframe with an exposed portion configured to electrically and/or mechanically couple the package to a support.

17. The packaging system of claim 16, further comprising:
a contact clip thermally and electrically coupled to the electronic chip,
wherein the contact clip is partially exposed by the encapsulant.

18. The packaging system of claim 17, further comprising:
an exposed outlead terminal at a first side of the package body and forming at least part of the heat transfer surface.

19. The packaging system of claim 11, wherein the heat transfer surface has an area amounting to at least 30% and to less than 100% of a total area of a first side of the package body.

20. The packaging system of claim 11, wherein the electronic chip is a power semiconductor chip having a first load terminal and a second load terminal.

21. A method of manufacturing a heat dissipation device comprising a first part and a second part, the method comprising:
providing the first part, the first part comprising a first material and having a surface portion, the first part further comprising a barrier layer and/or an adhesion layer and/or an adhesion promotion layer; and
depositing particles of a second material on the surface portion to form the second part.

22. The method of claim 21, wherein depositing the particles of the second material comprises:
transporting the particles in a fluid stream onto the surface portion,
wherein the fluid stream has a velocity of at least 20% of a velocity of sound in the fluid,
wherein the fluid stream is a gas.

23. The method of claim 22, further comprising:
providing a plasma,
wherein the fluid stream comprises the plasma.

24. The method of claim 23, wherein the plasma is configured to provide the particles as reactive particles.

25. The method of claim 21, wherein the particles of the second material are deposited by spray coating or plasma spray coating.

26. An electronic apparatus, comprising:
a support; and
a packaging system mounted to the support, the packaging system comprising:
a package comprising an electronic chip, the package having a package body encapsulating the electronic chip, the package body having an exposed heat transfer surface made of metal; and
a heat dissipation device thermally coupled to the heat transfer surface, the heat dissipation device comprising a first part comprising a first material and having a surface portion, and a second part directly coupled to the surface portion and comprising a second material, the second part having a porosity, the first part further comprising a barrier layer and/or an adhesion layer and/or an adhesion promotion layer.

27. The electronic apparatus of claim 26, wherein the support is a printed circuit board.

28. A method of manufacturing an electronic apparatus, the method comprising:
mounting a package to a support, the package comprising an electronic chip;
thermally coupling a heat dissipation device to the package, the heat dissipation device comprising:
a first part comprising a first material and having a surface portion; and
a second part directly coupled to the surface portion and comprising a second material,
wherein the second part has a porosity,
wherein the first part further comprises a barrier layer and/or an adhesion layer and/or an adhesion promotion layer.

29. A method of manufacturing a packaging system, the method comprising:
providing a package comprising an electronic chip; and
mounting a heat dissipation device to the package, the heat dissipation device comprising:
a first part comprising a first material and having a surface portion; and
a second part directly coupled to the surface portion and comprising a second material,
wherein the second part has a porosity,
wherein the first part further comprises a barrier layer and/or an adhesion layer and/or an adhesion promotion layer.
